(19) United States
(12) Patent Application Publication
(10) Pub. No.: US 2014/0209976 A1
(43) Pub. Date: Jul. 31, 2014

(54) TRANSISTORS AND METHODS OF MANUFACTURING THE SAME

(71) Applicant: SAMSUNG ELECTRONICS CO., LTD., Suwon-si (KR)

(72) Inventors: Chang-Jae Yang, Seoul (KR); Sang-Su KIM, Yongin-si (KR); Jung-Dal CHOI, Hwaseong-si (KR); Sung-Gi HUR, Hwaseong-si (KR)

(73) Assignee: SAMSUNG ELECTRONICS CO., LTD., Suwon-si (KR)

(21) Appl. No.: 14/163,972

(22) Filed: Jan. 24, 2014

(30) Foreign Application Priority Data
Jan. 25, 2013 (KR) 10-2013-0008497

(51) Int. Cl. H01L 29/78; H01L 29/10

(52) U.S. Cl. CPC H01L 29/7849; H01L 29/1054
USPC 257/190; 438/285

(57) ABSTRACT

A transistor and a method of manufacturing the same are disclosed. The transistor includes a first epitaxial layer, a channel layer, a gate structure and an impurity region. The first epitaxial layer on a substrate includes a silicon-germanium-tin (SiₓGe_{1-x-y}Sn_{y}) single crystal having a lattice constant greater than a lattice constant of a germanium (Ge) single crystal. The channel layer is disposed adjacent to the first epitaxial layer. The channel layer includes the germanium single crystal. The gate structure is disposed on the channel layer. The impurity region is disposed at an upper portion of the channel layer adjacent to the gate structure.

### CLAIM FOR PRIORITY

This application claims priority under 35 USC §119 to Korean Patent Application No. 10-2013-0008497, filed Jan. 25, 2013 in the Korean Intellectual Property Office (KIPO), the contents of which are hereby incorporated herein by reference in their entirety.

### FIELD

Example embodiments relate to transistors and methods of manufacturing the same.

### BACKGROUND

By generating a tensile stress (or strain) or a compressive stress in a channel region of a transistor, the mobility of carriers in the channel region can be improved. For example, in the case of a P-channel metal oxide semiconductor (PMOS) transistor, a compressive stress is applied to the channel region between a source region and a drain region. On the other hand, in the case of a N-channel metal oxide semiconductor (NMOS) transistor, a tensile stress is applied to the channel region.

Therefore, a structure and a material may be used to apply sufficient stress to the channel region of the transistor.

### SUMMARY

Example embodiments provide a transistor having improved carrier mobility and a reduced leakage current.

Example embodiments provide a method of manufacturing a transistor having improved carrier mobility and a reduced leakage current.

According to example embodiments, there is provided a transistor including a first epitaxial layer, a channel layer, a gate structure and an impurity region. The first epitaxial layer on a substrate includes a silicon-germanium-tin (SiₓGe_{1-x-y}Sn_{y}) single crystal having a lattice constant greater than a lattice constant of a germanium (Ge) single crystal. The channel layer is disposed adjacent to the first epitaxial layer. The channel layer includes the germanium single crystal. The gate structure is disposed on the channel layer. The impurity region is disposed at an upper portion of the channel layer adjacent to the gate structure.

In example embodiments, the silicon-germanium-tin single crystal may have an energy bandgap greater than an energy bandgap of the germanium single crystal.

In example embodiments, the first epitaxial layer may fill a lower portion of a recess on the substrate, and the channel layer may fill an upper portion of the recess on the substrate.

In example embodiments, the transistor may further include a barrier layer between the first epitaxial layer and the channel layer, and the barrier layer may include a material having an energy bandgap greater than that of the germanium single crystal.

In example embodiments, the transistor may further include a second epitaxial layer disposed under the first epitaxial layer, the substrate may include includes a silicon (Si) single crystal, and the second epitaxial layer includes a single crystal having a lattice constant less than a lattice constant of the silicon-germanium-tin single crystal and greater than a lattice constant of the silicon single crystal.

In example embodiments, the transistor may further include a capping layer between the channel layer and the gate structure, and the capping layer may include silicon.

According to example embodiments, there is provided a transistor including an epitaxial layer, a protrusion portion, a channel layer and a gate structure. The epitaxial layer is disposed on a substrate. The epitaxial layer includes a silicon-germanium-tin (SiₓGe_{1-x-y}Sn_{y}) single crystal having a lattice constant greater than a lattice constant of a germanium (Ge) single crystal. The protrusion portion projects from an upper surface of the epitaxial layer. The protrusion portion extends in a first direction. The channel layer pattern extends in the first direction on the protrusion portion. The channel layer pattern includes the germanium single crystal. The gate structure is disposed on sidewalls of the protrusion portion and the channel layer and an upper surface of the channel layer. The gate structure extends in a second direction substantially perpendicular to the first direction.

According to example embodiments, there is provided a method of manufacturing a transistor. In the method, an upper portion of the substrate is partially removed to form a recess. A first epitaxial layer is formed to fill a lower portion of the recess. The first epitaxial layer includes a silicon-germanium-tin (SiₓGe_{1-x-y}Sn_{y}) single crystal having a lattice constant greater than a lattice constant of a germanium (Ge) single crystal. A channel layer is formed to fill an upper portion of the recess. The channel layer includes the germanium (Ge) single crystal. A gate structure is formed on the channel layer. Impurities are implanted at an upper portion of the channel layer adjacent to the gate structure.

In example embodiments, forming the first epitaxial layer may include performing a selective epitaxial growth process using a silicon source, a germanium source and a tin source.

In example embodiments, the silicon-germanium-tin single crystal may have an energy bandgap greater than an energy bandgap of the germanium single crystal.

In example embodiments, after forming the first epitaxial layer, a heat treatment process may be performed about the first epitaxial layer.

In example embodiments, forming the channel layer may include performing a selective epitaxial growth process to form a preliminary channel layer filling the recess and planarizing the preliminary channel layer.

In example embodiments, before forming the channel layer, a barrier layer may be formed by performing a selective epitaxial growth process on the first epitaxial layer, and the barrier layer may have an energy bandgap greater than an energy bandgap of the germanium single crystal.

In example embodiments, after forming the channel layer, a capping layer including silicon may be formed on the channel layer.

In example embodiments, before forming the first epitaxial layer, a second epitaxial layer may be formed to fill a lower portion of the recess. The substrate may include a silicon single crystal, and the second epitaxial layer may include a single crystal having a lattice constant less than a lattice constant of the silicon-germanium-tin single crystal and greater than a lattice constant of the silicon single crystal.

According to example embodiments, a transistor may include a channel layer containing a germanium (Ge) single crystal and a first epitaxial layer containing a silicon-germanium-tin (SiₓGe_{1-x-y}Sn_{y}) single crystal under the channel layer. The first epitaxial layer may include the silicon-germanium-tin (SiₓGe_{1-x-y}Sn_{y}) single crystal which may have a lattice constant larger than that of the germanium (Ge) single crystal of the channel layer, and may have an energy bandgap larger than that of the germanium (Ge) single crystal of the channel layer. Therefore, the transistor may have improved carrier mobility due to the tensile stress on the channel layer and a reduced leakage current due to the carrier confinement effect.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a cross-sectional view illustrating a transistor in accordance with example embodiments;

FIGS. 2 to 7 are cross-sectional views illustrating a method of manufacturing a transistor in accordance with example embodiments;

FIG. 8 is a cross-sectional view illustrating a transistor in accordance with example embodiments;

FIG. 9 is a cross-sectional view illustrating a transistor in accordance with example embodiments;

FIG. 10 is a cross-sectional view illustrating a transistor in accordance with example embodiments;

FIG. 11 is a cross-sectional view illustrating a transistor in accordance with example embodiments;

FIGS. 12 to 17 are cross-sectional views illustrating a method of manufacturing a transistor in accordance with example embodiments;

FIG. 18 is a perspective view illustrating a transistor in accordance with example embodiments;

FIG. 19 is a perspective view illustrating a transistor in accordance with example embodiments;

FIG. 20 is a graph showing a lattice constant of silicon-germanium-tin (SiₓGe_{1-x-y}Sn_{y}) single crystal depending on the composition;

FIG. 21 is a graph showing an energy bandgap of silicon-germanium-tin (SiₓGe_{1-x-y}Sn_{y}) single crystal depending on the composition; and

FIG. 22 is a graph in which the line of FIG. 20 and the line IV-IV′ of FIG. 21 are overlapped.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Hereinafter, example embodiments will be explained in detail with reference to the accompanying drawings.

FIG. 1 is a cross-sectional view illustrating a transistor in accordance with example embodiments.

Referring to FIG. 1, the transistor may include a first epitaxial layer 120, a channel layer 130, a gate structure 140, a spacer 150, and an impurity region 160 disposed at an upper portion of a substrate 100.

The substrate 100 may include a semiconductor substrate. For example, the substrate 100 may include a silicon substrate, a germanium substrate or a silicon-germanium substrate, a silicon-on-insulator (SOI) substrate or a germanium-on-insulator (GOI) substrate. An isolation layer pattern 110 may be disposed on the upper portion of the substrate 100, so that an active region and a field region of the substrate 100 may be defined.

The first epitaxial layer 120 may fill a lower portion of a first recess 115 disposed on the upper portion of the substrate 100 between the isolation layer pattern 110. The first epitaxial layer 120 may include a single crystal. In example embodiments, the first epitaxial layer 120 may include a silicon-germanium-tin (SiₓGe_{1-x-y}Sn_{y}) single crystal.

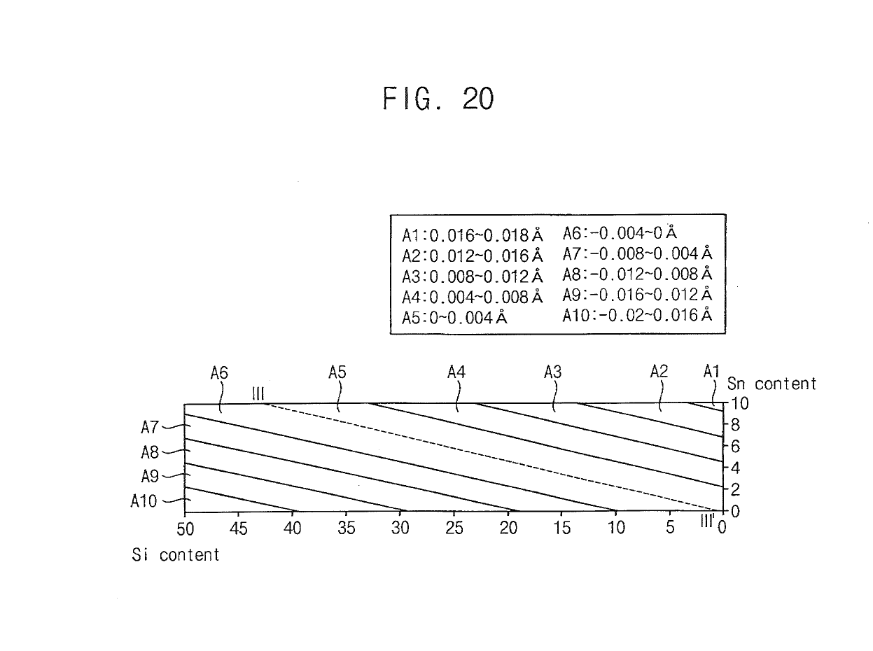

A lattice constant of the silicon-germanium-tin (SiₓGe_{1-x-y}Sn_{y}) single crystal may vary depending on the composition of the silicon-germanium-tin (SiₓGe_{1-x-y}Sn_{y}) single crystal. Referring to FIG. 20, as the concentration of silicon (Si) increases, the lattice constant of the silicon-germanium-tin (SiₓGe_{1-x-y}Sn_{y}) single crystal may decrease. While the concentration of tin (Sn) increases, the lattice constant of the silicon-germanium-tin (SiₓGe_{1-x-y}Sn_{y}) single crystal may increase. A line of FIG. 20 represents a composition of the silicon-germanium-tin (SiₓGe_{1-x-y}Sn_{y}) single crystal, which has a lattice constant the same as that of a germanium (Ge) single crystal. That is, if a silicon-germanium-tin (SiₓGe_{1-x-y}Sn_{y}) single crystal has a composition of the upper right region from the line the silicon-germanium-tin (SiₓGe_{1-x-y}Sn_{y}) single crystal may have a lattice constant substantially larger than that of the germanium (Ge) single crystal. The first epitaxial layer 120 may include the silicon-germanium-tin (SiₓGe_{1-x-y}Sn_{y}) single crystal which has the composition of the upper right region from the line

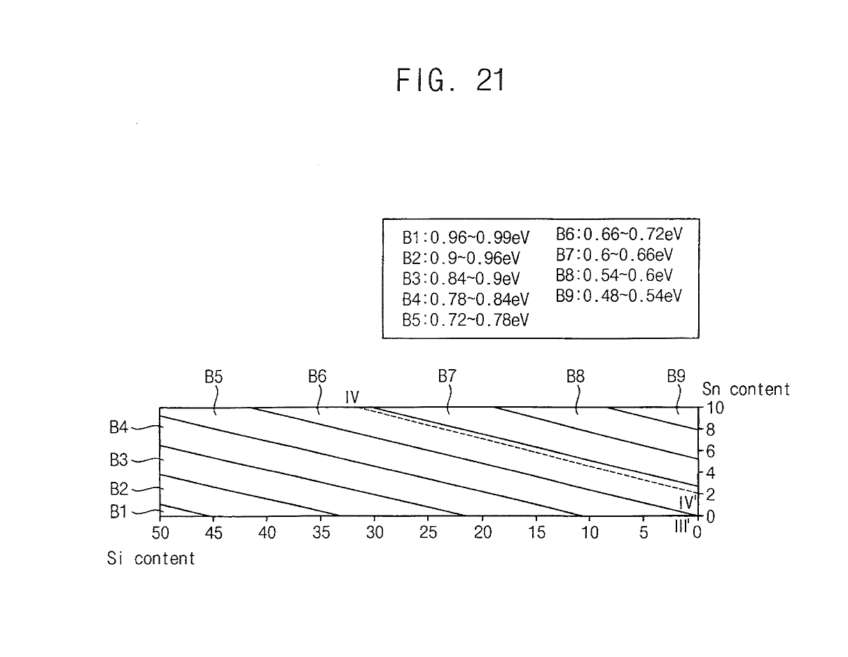

On the other hand, an energy gap of the silicon-germanium-tin (SiₓGe_{1-x-y}Sn_{y}) single crystal may vary depending on the composition of the silicon-germanium-tin (SiₓGe_{1-x-y}Sn_{y}) single crystal. Referring to FIG. 21, as the concentration of silicon (Si) increases, the energy bandgap of the silicon-germanium-tin (SiₓGe_{1-x-y}Sn_{y}) single crystal may increase. While the concentration of tin (Sn) increases, the energy bandgap of the silicon-germanium-tin (SiₓGe_{1-x-y}Sn_{y}) single crystal may decrease. A line IV-IV′ of FIG. 21 represents a composition of the silicon-germanium-tin (SiₓGe_{1-x-y}Sn_{y}) single crystal, which has an energy bandgap the same as that of a germanium (Ge) single crystal. That is, if a silicon-germanium-tin (SiₓGe_{1-x-y}Sn_{y}) single crystal has a composition of the lower left region from the line IV-IV′, the silicon-germanium-tin (SiₓGe_{1-x-y}Sn_{y}) single crystal may have an energy bandgap substantially larger than that of the germanium (Ge) single crystal. The first epitaxial layer 120 may include the silicon-germanium-tin (SiₓGe_{1-x-y}Sn_{y}) single crystal, which has the composition of the lower left region from the line IV-IV′.

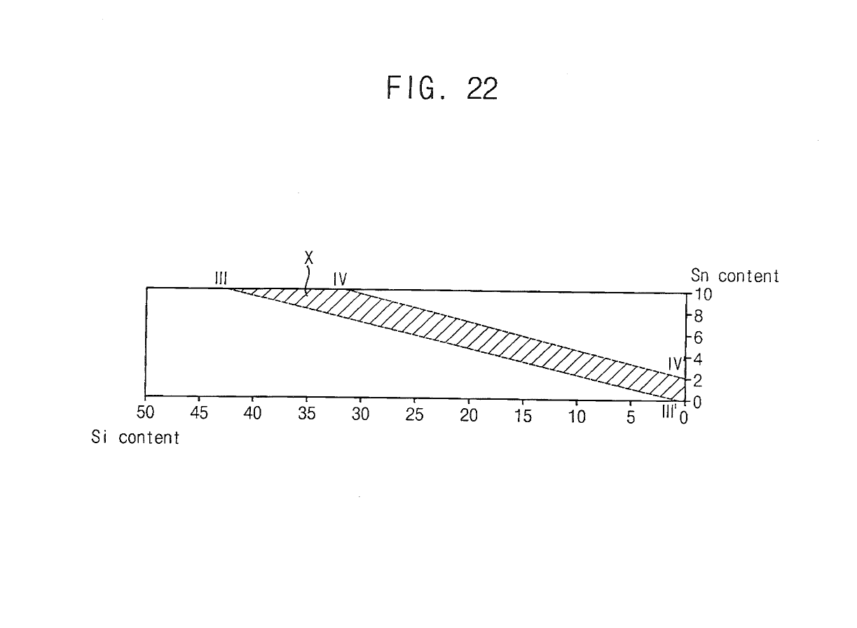

FIG. 22 is a graph in which the line of FIG. 20 and the line IV-IV′ of FIG. 21 are overlapped. The first epitaxial layer 120 may include the silicon-germanium-tin (SiₓGe_{1-x-y}Sn_{y}) single crystal, which has a composition between the line of FIG. 20 and the line IV-IV′ of FIG. 21. That is, the composition of the silicon-germanium-tin (SiₓGe_{1-x-y}Sn_{y}) single crystal may be determined to be positioned in the region X between the line III-III′ of FIG. 20 and the line IV-IV′ of FIG. 21.

Therefore, the first epitaxial layer 120 may include the silicon-germanium-tin (SiₓGe_{1-x-y}Sn_{y}) single crystal, which may have a lattice constant larger than that of the germanium single crystal, and may have an energy bandgap larger than that of the germanium single crystal.

The channel layer 130 may fill an upper portion of the first recess 115 on the substrate 100. In this case, a top surface of the channel layer 130 may have the same height as the top surface of the substrate 100 and the isolation layer pattern 110.

The channel layer 130 may include a germanium single crystal. In example embodiments, the channel layer 130 may comprise the germanium (Ge) single crystal, and the germanium (Ge) single crystal may form a continuous lattice structure with the silicon-germanium-tin (SiₓGe_{1-x-y}Sn_{y}) single crystal of the first epitaxial layer 120. The germanium (Ge) single crystal may have a carrier mobility larger than that of the silicon (Si) single crystal. Therefore, a transistor including the germanium (Ge) single crystal as a channel region may have a higher speed than a transistor including the silicon single crystal as a channel region.

The silicon-germanium-tin (SiₓGe_{1-x-y}Sn_{y}) single crystal of the first epitaxial layer 120 may have a lattice constant larger than that of the germanium (Ge) single crystal of the channel layer 130, so that the first epitaxial layer 120 may apply a tensile stress to the channel layer 130. Therefore, electron mobility in the channel layer 130 may increase.

Further, the silicon-germanium-tin (SiₓGe_{1-x-y}Sn_{y}) single crystal of the first epitaxial layer 120 may have an energy bandgap larger than that of the germanium single crystal of the channel layer 130, so that electrons in the channel layer 130 may not leak to the first epitaxial layer 120 due to a carrier confinement effect. Therefore, a leakage current of the transistor may be reduced.

The gate structure 140 may include a gate insulation layer pattern 142, a gate electrode 144 and a gate mask sequentially stacked on the channel layer 130. In example embodiments, the gate insulation layer pattern 142 may include a high-K dielectric material, such as HfO₂, HfON, HfSi₂O, HfSiO, HfSiON, HfAlO, HfLaO, La₂O₃ or a mixture thereof. However, the high-K dielectric material may not be limited thereto.

Further, the spacer 150 may be disposed on a sidewall of the gate structure 140. For example, the spacer 150 may include silicon oxide, silicon nitride and/or silicon oxy nitride. In example embodiments, the spacer 150 may have a single layer structure or a multi layer structure.

The impurity region 160 may be disposed at the upper portion of the channel region 130 adjacent to the gate structure 140. In example embodiments, at least two impurity regions 160 may be disposed adjacent to the gate structure, and may be spaced apart from each other. The impurity regions 160 may include an n-type impurity, such as phosphorous (P), arsenic (As), and the like. The impurity regions 160 may serve as a source region and a drain region of the transistor.

According to an example embodiment, the transistor may include the channel layer 130 containing the germanium single crystal and the first epitaxial layer 120 containing the silicon-germanium-tin (SiₓGe_{1-x-y}Sn_{y}) single crystal under the channel layer 130. The first epitaxial layer 120 may include the silicon-germanium-tin (SiₓGe_{1-x-y}Sn_{y}) single crystal, which may have a lattice constant larger than that of the germanium single crystal of the channel layer 130, and may have an energy bandgap larger than that of the germanium single crystal of the channel layer 130. Therefore, the transistor may have improved carrier mobility due to the tensile stress on the channel layer 130 and a reduced leakage current due to the carrier confinement effect.

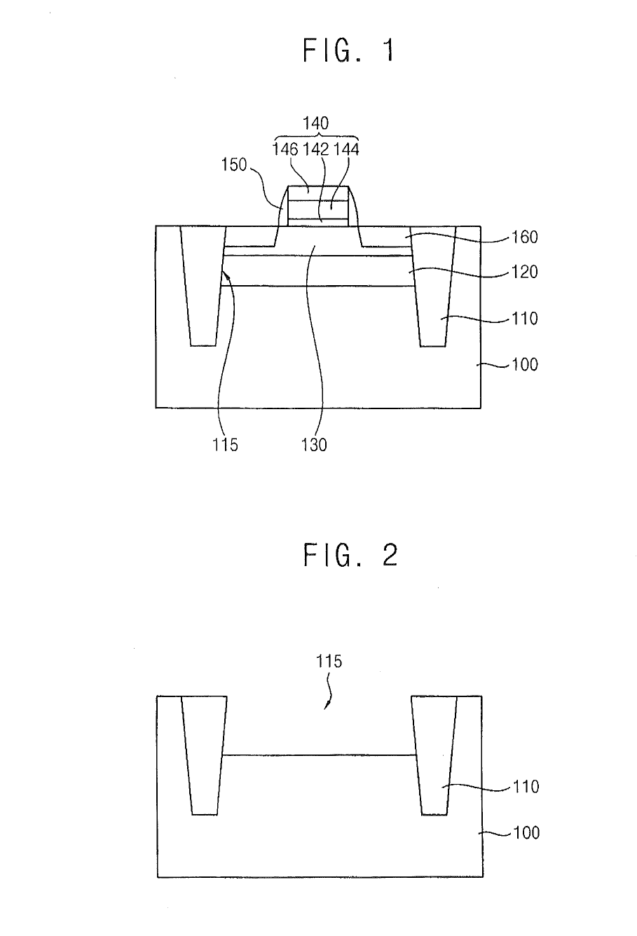

FIGS. 2 to 7 are cross-sectional views illustrating a method of manufacturing a transistor in accordance with example embodiments.

Referring to FIG. 2, an isolation layer pattern 110 may be formed at an upper portion of a substrate 100, and then the substrate 100 may be partially removed to form a first recess 115.

The substrate 100 may include a semiconductor substrate. For example, the substrate 100 may include a silicon substrate, a germanium substrate or a silicon-germanium substrate, a silicon-on-insulator (SOI) substrate or a germanium-on-insulator (GOI) substrate. In example embodiments, the substrate 100 may include a single crystal.

The substrate 100 may be partially etched to form a first trench, an insulation layer may be formed on the substrate 100 to fill the first trench, and the insulation layer may be planarized until a top surface of the substrate 100 is exposed thereby forming the isolation layer pattern 110.

In example embodiments, the insulation layer may be formed using silicon oxide such as MTO oxide, HDP oxide, CVD oxide, and the like. The planarization process may include a chemical mechanical polish (CMP) process and/or an etch-back process. As the isolation layer pattern 110 is formed, the substrate 100 may be divided into an active region and a field region where the isolation layer pattern 110 is disposed.

Then a first recess 115 may be formed using an etching process using the isolation layer pattern as an etching mask, or using additional mask on the isolation layer pattern 110 and the substrate 100 as an etching mask. In example embodiments, a bottom surface of the first recess may be higher than a bottom surface of the isolation layer pattern 110.

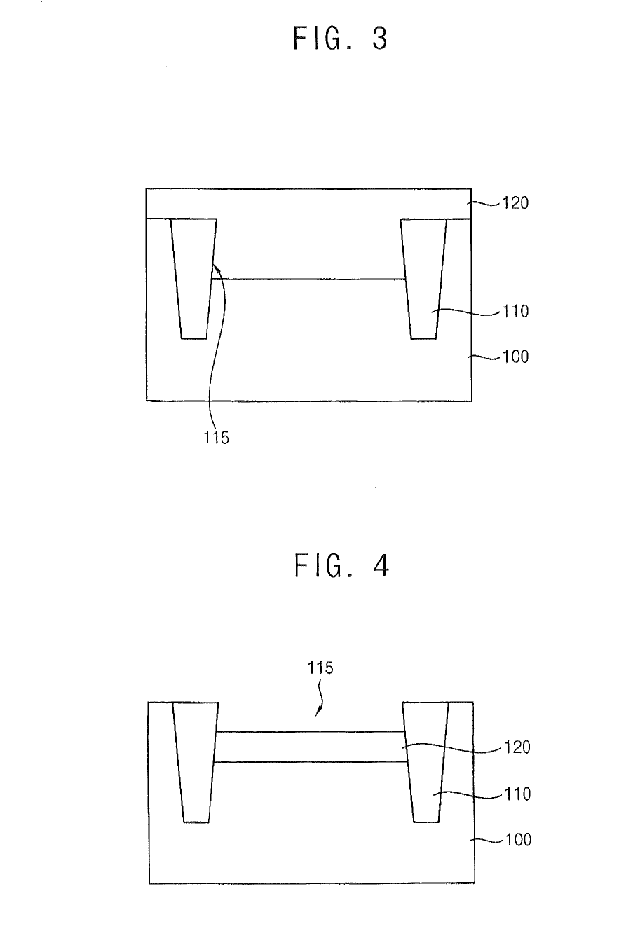

Referring to FIG. 3, a first epitaxial layer 120 may be formed on the substrate 100 and the isolation layer pattern 110 to fill the first recess 115.

The first epitaxial layer 120 may be formed by performing a selective epitaxial growth (SEG) process on an inner wall of the first recess 115. The first epitaxial layer 120 may include a silicon-germanium-tin (SiₓGe_{1-x-y}Sn_{y}) single crystal. In example embodiments, the silicon-germanium-tin (SiₓGe_{1-x-y}Sn_{y}) single crystal may form a continuous lattice structure with the single crystal of the substrate 100.

The SEG process may include a chemical vapor deposition (CVD) process, a low pressure CVD (LPCVD) process, ultra high vacuum CVD (UHV-CVD) process, etc. using a silicon source, a germanium source and a tin source. In example embodiments, the composition of the first epitaxial layer 120 may be adjusted by changing the input rates of the silicon source, the germanium source and the tin source.

The silicon-germanium-tin (SiₓGe_{1-x-y}Sn_{y}) single crystal of the first epitaxial layer 120 may be formed to have a predetermined lattice constant and a predetermined energy bandgap. The silicon-germanium-tin (SiₓGe_{1-x-y}Sn_{y}) single crystal may have a lattice constant larger than that of the germanium (Ge) single crystal, and may have an energy bandgap larger than that of the germanium (Ge) single crystal.

As mentioned above, the first epitaxial layer 120 may include the silicon-germanium-tin (SiₓGe_{1-x-y}Sn_{y}) single crystal which has a composition between the line of FIG. 20 and the line IV-IV′ of FIG. 21.

Then, a heat treatment process may be performed about the first epitaxial layer 120 to relax a remaining stress in the first epitaxial layer 120. Therefore, a crystal defect such as a dislocation in the first epitaxial layer 120 may be reduced.

Referring to FIG. 4, an upper portion of the first epitaxial layer 120 may be removed.

The upper portion of the first epitaxial layer 120 may be removed by an etch back process or an etching process, so that a top surface of the remaining first epitaxial layer 120 may be lower than a top surface of the first isolation layer pattern 110. That is, the remaining first epitaxial layer 120 may fill a lower portion of the first recess 115.

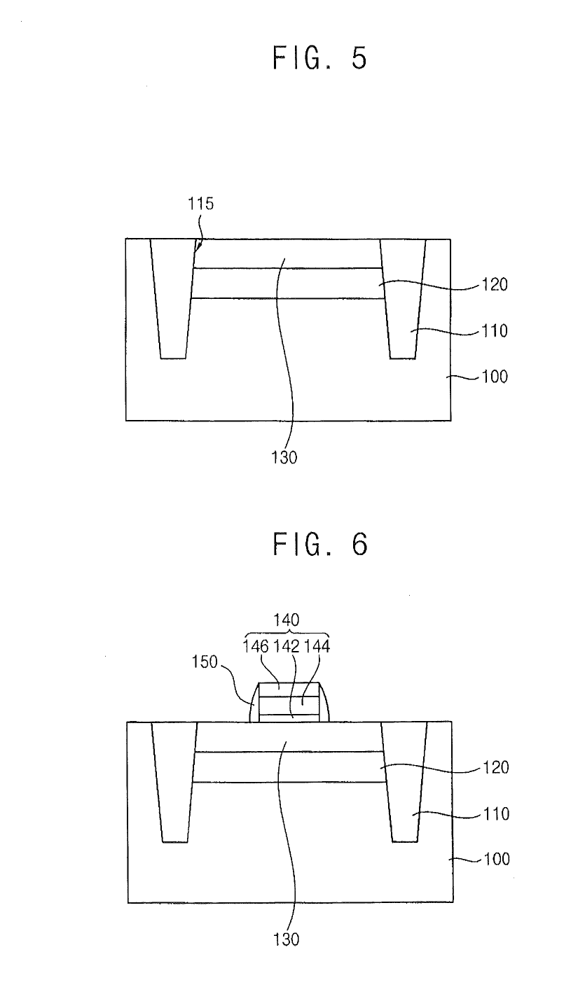

Referring to FIG. 5, a channel layer 130 may be formed to fill an upper portion of the first recess 115.

A preliminary channel layer may be formed on the substrate 100, the isolation layer pattern 110 and the first epitaxial layer 120 to fill the first recess 115, and the preliminary channel layer may be planarized until a top surface of the substrate 100 is exposed, thereby forming the channel layer 130.

In example embodiments, the preliminary channel layer may be formed by a selective epitaxial growth (SEG) process. The preliminary channel layer may include a germanium (Ge) single crystal. In an example embodiment, the preliminary channel layer may consist essentially of the germanium (Ge) single crystal. Further, the planarization process may include a CMP process and/or an etch back process.

The germanium single crystal of the channel layer 130 may form a continuous lattice structure with the silicon-germanium-tin (SiₓGe_{1-x-y}Sn_{y}) single crystal of the first epitaxial layer 120, and may have a lattice constant substantially smaller than that of the silicon-germanium-tin (SiₓGe_{1-x-y}Sn_{y}) single crystal of the first epitaxial layer 120. Therefore, the first epitaxial layer 120 may apply a tensile stress to the channel layer 130.

Further, The silicon-germanium-tin (SiₓGe_{1-x-y}Sn_{y}) single crystal of the first epitaxial layer 120 may has an energy bandgap larger than that of the germanium (Ge) single crystal of the channel layer 130, so that electron in the channel layer 130 may not leak to the first epitaxial layer 120 due to a carrier confinement effect. Therefore, a leakage current of the transistor may be improved.

Referring to FIG. 6, a gate structure 140 may be formed on the channel layer 130.

The gate structure 140 may be formed by sequentially forming a gate insulation layer, a gate electrode layer and a gate mask layer, and by patterning the gate insulation layer, the gate electrode layer and the gate mask layer. Therefore, the gate structure 140 may include a gate insulation layer pattern 142, a gate electrode 144 and a gate mask 146, which may be sequentially stacked on the channel layer 130. In example embodiments, a plurality of gate structures 140 may be formed on the channel layer 130.

In example embodiments, the gate insulation layer may be formed using a metal oxide having a relatively high dielectric constant by a chemical vapor deposition (CVD) process, a plasma enhanced CVD process, a high density plasma CVD process, an atomic layer deposition process, and the like. For example, the gate insulation layer may include HfO₂, HfON, HfSi₂O, HfSiO, HfSiON, HfAlO, HfLaO, La₂O₃ or a mixture thereof.

Then, a spacer layer may be formed on the substrate 100 and the isolation layer pattern 110 to cover the gate structure 140, and the spacer layer may be ansiotropically etched to form a spacer 150 on a sidewall of the gate structure 140. For example, the spacer 150 may include silicon oxide, silicon nitride or silicon oxynitride.

In other example embodiments, an interfacial layer (not shown) may be formed on the channel layer 130 before forming the gate insulation layer. For example, the interfacial layer may be formed by thermally oxidizing the channel layer 130. That is, the interfacial layer may include germanium oxide.

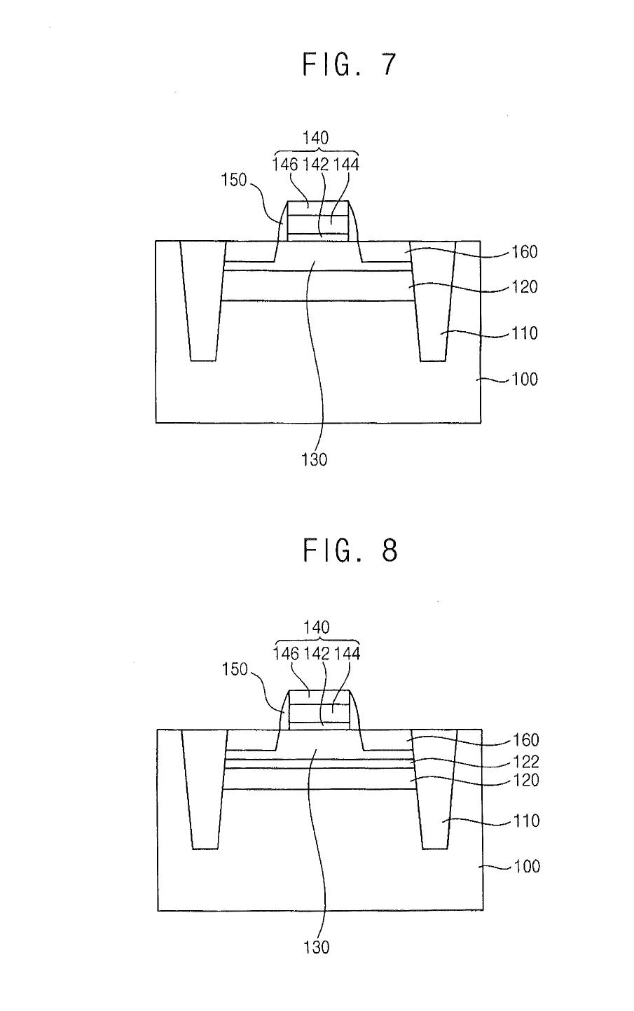

Referring to FIG. 7, an impurity region 160 may be formed at an upper portion of the channel layer 130 adjacent to the gate structure 140.

The impurity region 160 may be formed by implanting an n-type impurity into the upper portion of the channel layer 130. For example, the n-type impurity may include phosphorous (P), arsenic (As), and the like. Further, an additional heat treatment process may be performed to activate the n-type impurity in the channel layer 130. Accordingly, the channel layer 130, the gate structure 140 and the impurity region 160 may define an NMOS transistor.

According to example embodiments, the first epitaxial layer 120 under the channel layer 130 may include the silicon-germanium-tin (SiₓGe_{1-x-y}Sn_{y}) single crystal, which may have a lattice constant larger than that of the germanium (Ge) single crystal of the channel layer 130, and may have an energy bandgap larger than that of the germanium (Ge) single crystal of the channel layer 130. Therefore, the transistor may have improved carrier mobility due to the tensile stress on the channel layer 130 and a reduced leakage current due to the carrier confinement effect.

FIG. 8 is a cross-sectional view illustrating a transistor in accordance with example embodiments. The transistor may be substantially the same as or substantially similar to the transistor described with reference to FIG. 1 except for the barrier layer 122. Thus, like reference numerals refer to like elements, and repetitive explanations thereof may be omitted herein.

Referring to FIG. 8, the transistor may include a first epitaxial layer 120, a barrier layer 122, a channel layer 130, a gate structure 140, a spacer 150 and an impurity region 160.

The barrier layer 122 may be disposed between the first epitaxial layer 120 and the channel layer 130. The barrier layer 122 may include a single crystal having an energy bandgap substantially larger than that of the germanium (Ge) single crystal. The barrier layer 122 may reduce a leakage current from the channel layer 130 due to a carrier confinement effect. In an example embodiment, the barrier layer 122 may include a silicon-germanium (Si_{z}Ge_{i-z}) single crystal.

The first epitaxial layer 120 may include a silicon-germanium-tin (SiₓGe_{1-x-y}Sn_{y}) single crystal having a lattice constant substantially larger than that of the germanium (Ge) single crystal. Therefore, the first epitaxial layer 120 may apply a tensile stress to the channel layer 130. Further, an energy bandgap of the silicon-germanium-tin (SiₓGe_{1-x-y}Sn_{y}) single crystal of the first epitaxial layer 120 may not be limited, when the barrier layer 122 is disposed between the first epitaxial layer 120 and the channel layer 130.

The transistor described with reference to FIG. 8 may be manufactured by a method substantially the similar to the method described with reference to FIGS. 2 to 7. However, the barrier layer 122 may be formed by a SEG process.

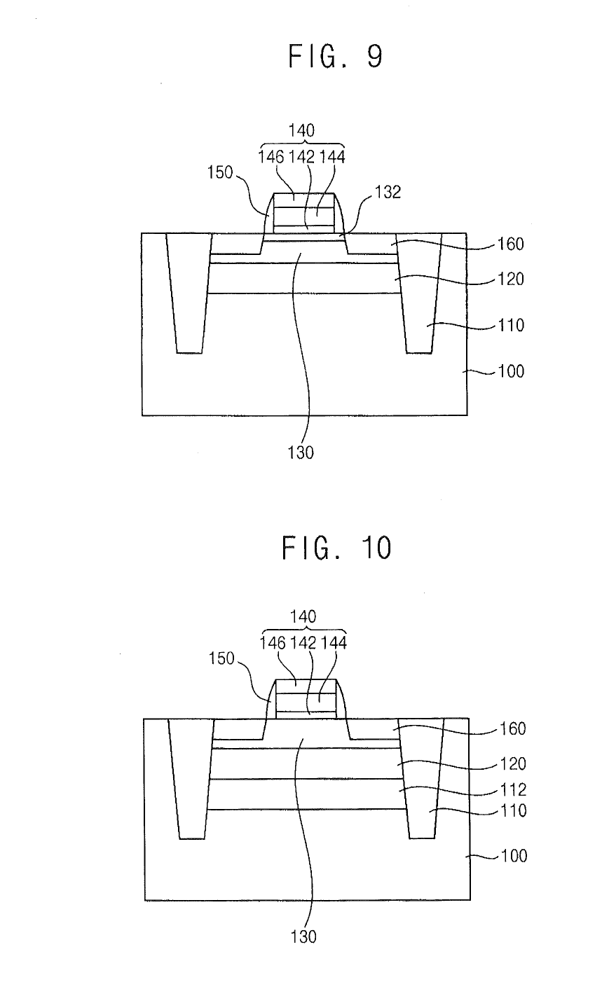

FIG. 9 is a cross-sectional view illustrating a transistor in accordance with example embodiments. The transistor may be substantially the same as or substantially similar to the transistor described with reference to FIG. 1 except for the capping layer 132. Thus, like reference numerals refer to like elements, and repetitive explanations thereof may be omitted herein.

Referring to FIG. 9, the transistor may include a first epitaxial layer 120, a channel layer 130, a capping layer 132, a gate structure 140, a spacer 150 and an impurity region 160.

The capping layer 132 may be disposed between the channel layer 130 and the gate structure 140. In example embodiments, the capping layer may include a semiconductor material, such as silicon (Si). If the capping layer 132 includes silicon, the gate insulation layer pattern 142 or an interfacial layer (not illustrated) between the capping layer 132 and the gate insulation layer pattern 142 may include silicon oxide. Therefore, the capping layer 132 may improve an interfacial property between the channel layer 130 and the gate insulation layer pattern 142.

The transistor described with reference to FIG. 9 may be manufactured by a method substantially the similar to the method described with reference to FIGS. 2 to 7.

FIG. 10 is a cross-sectional view illustrating a transistor in accordance with example embodiments. The transistor may be substantially the same as or substantially similar to the transistor described with reference to FIG. 1 except for the second epitaxial layer 112. Thus, like reference numerals refer to like elements, and repetitive explanations thereof may be omitted herein.

Referring to FIG. 10, the transistor may include a first epitaxial layer 120, a second epitaxial layer 112, a channel layer 130, a gate structure 140, a spacer 150 and an impurity region 160.

The second epitaxial layer 112 may be disposed between the first epitaxial layer 120 and the substrate 100. The second epitaxial layer 112 may include a single crystal having a lattice constant substantially larger than that of a single crystal of the substrate 100 and substantially smaller than that of the silicon-germanium-tin (SiₓGe_{1-x-y}Sn_{y}) single crystal of the first epitaxial layer 120. When the substrate 100 includes a silicon (Si) single crystal, the second epitaxial layer 112 may include a silicon-germanium (Si_{z}Ge_{1-z}) single crystal, and the second epitaxial layer 112 a continuous lattice structure with the substrate 100 and the channel layer 130. The second epitaxial layer 112 may relax a compression stress applied to the channel layer 130 by the substrate 100, so that a crystal defect, such as a dislocation in the first epitaxial layer 120, may be reduced. When the first epitaxial layer 120 has few crystal defects, the first epitaxial layer 120 effectively apply a tensile stress to the channel layer 130. The second epitaxial layer 112 may be formed by a SEG process.

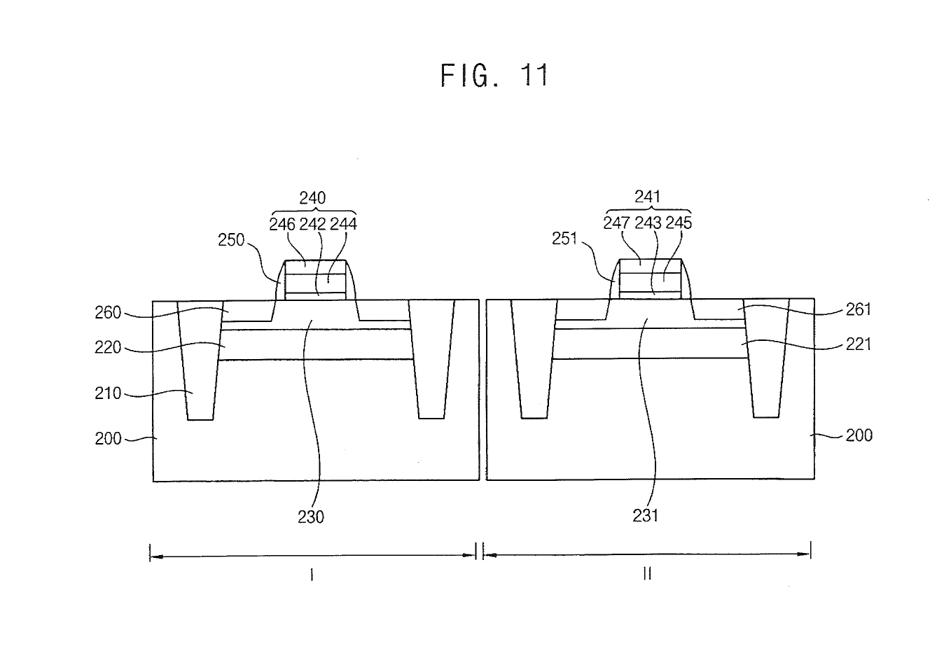

FIG. 11 is a cross-sectional view illustrating a transistor in accordance with example embodiments.

Referring to FIG. 11, the transistor may include an NMOS transistor in a first region I of a substrate 200 and a PMOS transistor in a second region II of the substrate 200.

The NMOS transistor may include a first gate structure 240, a first spacer 250, a first epitaxial layer 220, a first channel layer 230 and a first impurity region 260.

The first gate structure 240 may include a first gate insulation layer pattern 242, a first gate electrode 244 and a first gate mask 246. Further, the first spacer 250 may be disposed on a sidewall of the first gate structure 240.

The first impurity region 260 may be disposed adjacent the first gate structure 240. In example embodiments, a plurality of first impurity regions 260 may be disposed to be spaced apart from each other. For example, the first impurity region 260 may include an n-type impurity, such as phosphorous (P), arsenic (As), and the like.

The first channel layer 230 may be disposed between the first impurity regions 260 under the first gate structure 240. The first channel layer 230 may include a germanium single crystal.

The first epitaxial layer 220 may be disposed adjacent to the first channel layer 230. For example, the first epitaxial layer 220 may be disposed under the first channel layer 230. In example embodiments, the first epitaxial layer 220 may include a silicon-germanium-tin (SiₓGe_{1-x-y}Sn_{y}) single crystal, the silicon-germanium-tin (SiₓGe_{1-x-y}Sn_{y}) single crystal may have a composition substantially the same as those described with reference to FIG. 1. The first epitaxial layer 220 may apply a tensile stress to the first channel layer 230 to improve carrier mobility in the first channel layer 230.

The PMOS transistor may include a second gate structure 241, a second spacer 251, a second epitaxial layer 221, a second channel layer 231 and a second impurity region 261.

The second gate structure 241 may include a second gate insulation layer pattern 243, a second gate electrode 245 and a second gate mask 247. Further, the second spacer 251 may be disposed on a sidewall of the second gate structure 241.

The second impurity region 261 may be disposed adjacent the second gate structure 241. In example embodiments, a plurality of second impurity regions 261 may be disposed to be spaced apart from each other. For example, the second impurity region 260 may include a p-type impurity such as boron (B), gallium (Ga), and the like.

The second channel layer 231 may be deposed between the second impurity regions 261 under the second gate structure 241. The second channel layer 231 may include a germanium (Ge) single crystal.

The second epitaxial layer 221 may be disposed adjacent to the second channel layer 231. For example, the second epitaxial layer 221 may be disposed under the second channel layer 231. In example embodiments, the second epitaxial layer 221 may include a silicon-germanium (Si_{z}Ge_{1-z}) single crystal. The silicon-germanium (Si_{z}Ge_{1-z}) single crystal may have a lattice constant substantially smaller than that of the germanium (Ge) single crystal, and may have an energy bandgap substantially larger than that of the germanium (Ge) single crystal. Therefore, the second epitaxial layer 221 may apply a compression stress to the second channel layer 231, so that the second channel layer 231 may have improved carrier mobility. The holes in the second channel layer 231 may not leak to the second epitaxial layer 221 due to a carrier confinement effect.

According to example embodiments, the NMOS transistor may include the first epitaxial layer 220 including the silicon-germanium-tin (SiₓGe_{1-x-y}Sn_{y}) single crystal. The first epitaxial layer 220 may apply a tensile stress to the first channel layer 230, thereby improving electron mobility in the first channel layer 230. The PMOS transistor may include the second epitaxial layer 221 including the silicon-germanium (Si_{z}Ge_{1-z}) single crystal. The second epitaxial layer 221 may apply a compression stress to the second channel layer 231, thereby improving hole mobility in the second channel layer 231.

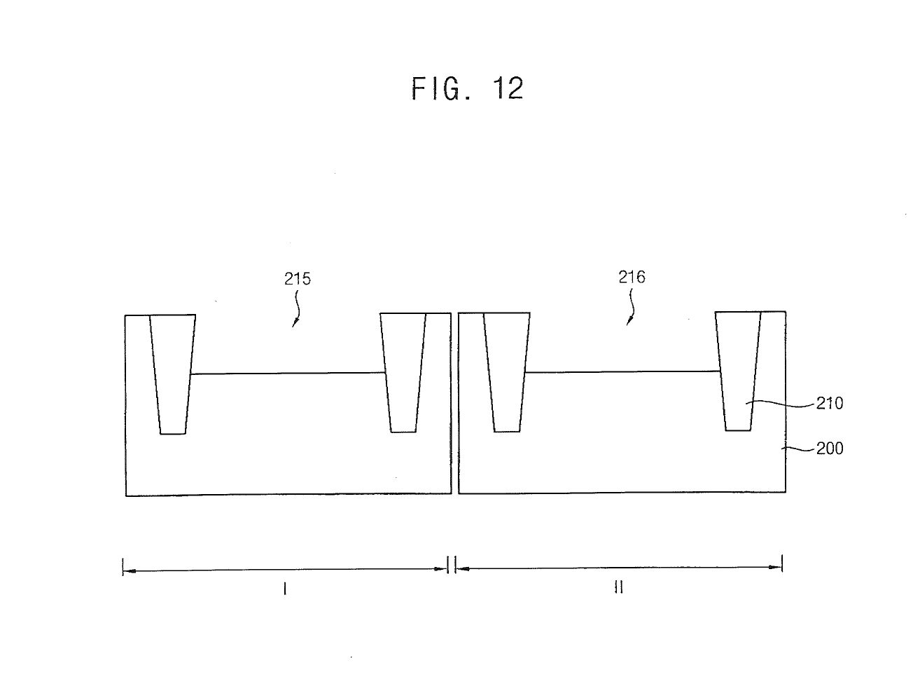

FIGS. 12 to 17 are cross-sectional views illustrating a method of manufacturing a transistor in accordance with example embodiments.

Referring to FIG. 12, an isolation layer pattern 210 may be formed at an upper portion of a substrate 200 including a first region I and a second region II, and then the substrate'200 may be partially removed to form a first recess 215 and a second recess 216 in the first region I and the second region II, respectively.

The substrate 200 may be partially etched to form a first trench, an insulation layer may be formed on the substrate 200 to fill the first trench, and the insulation layer may be planarized until a top surface of the substrate 200 is exposed thereby forming the isolation layer pattern 210. Then, a dry etching process may be performed to form the first recess 215 and the second recess 216 in the first region I and the second region II, respectively.

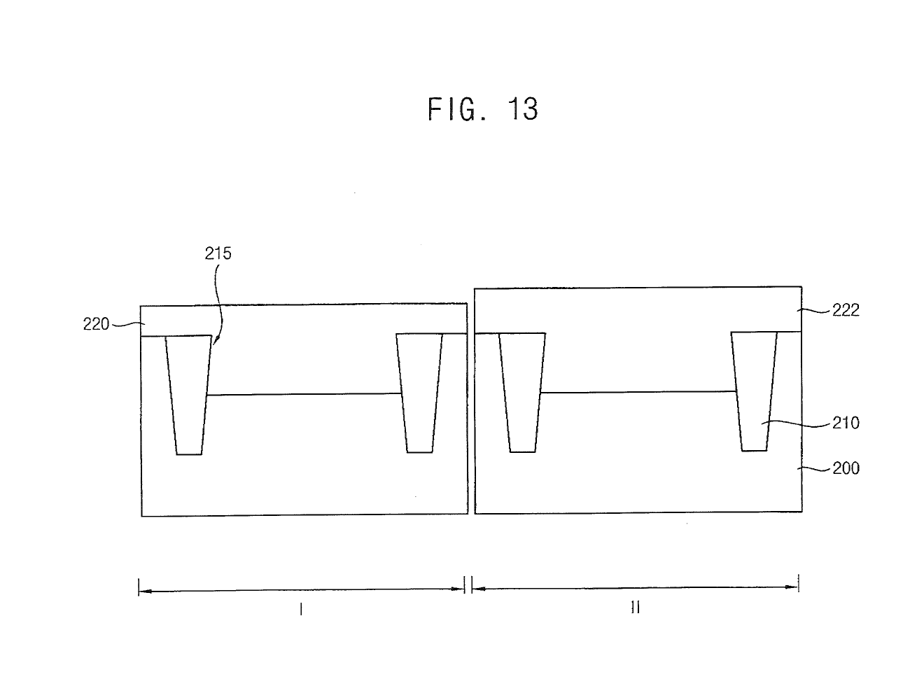

Referring to FIG. 13, after forming a first photoresist pattern 222 on the substrate 200 in the second region II, a first epitaxial layer 220 may be formed on the substrate 200 in the first region I to fill the first recess 215.

The first epitaxial layer 220 may be formed by performing a SEG process. In an example embodiment, the first epitaxial layer 220 may include a silicon-germanium-tin (SiₓGe_{1-x-y}Sn_{y}) single crystal, which may have a composition substantially the same as those described with reference to FIG. 1.

Then, the first photoresist pattern 222 may be removed by an ashing process or a strip process.

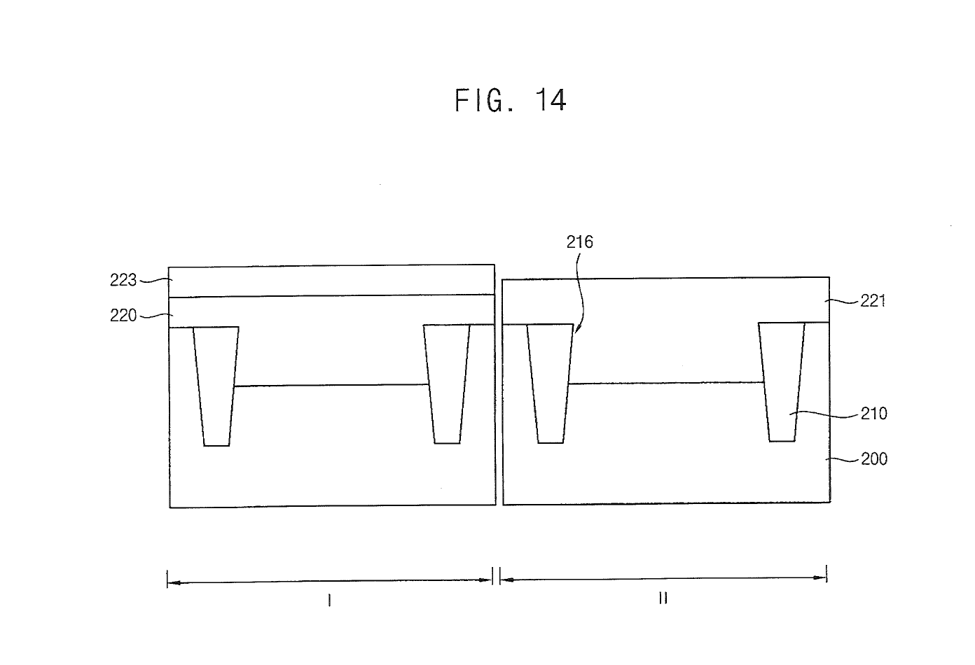

Referring to FIG. 14, after forming a second photoresist pattern 223 on the substrate 200 in the first region I, a second epitaxial layer 221 may be formed on the substrate 200 in the second region II to fill the second recess 216.

The second epitaxial layer 221 may be formed by performing a SEG process. In an example embodiment, the second epitaxial layer 221 may include a silicon-germanium (Si_{z}Ge_{1-z}) single crystal which may have a lattice constant substantially smaller than those of the germanium single crystal.

Then, the second photoresist pattern 223 may be removed by an ashing process or a strip process. A heat treatment process may be performed about the first epitaxial layer 220 and the second epitaxial layer 221.

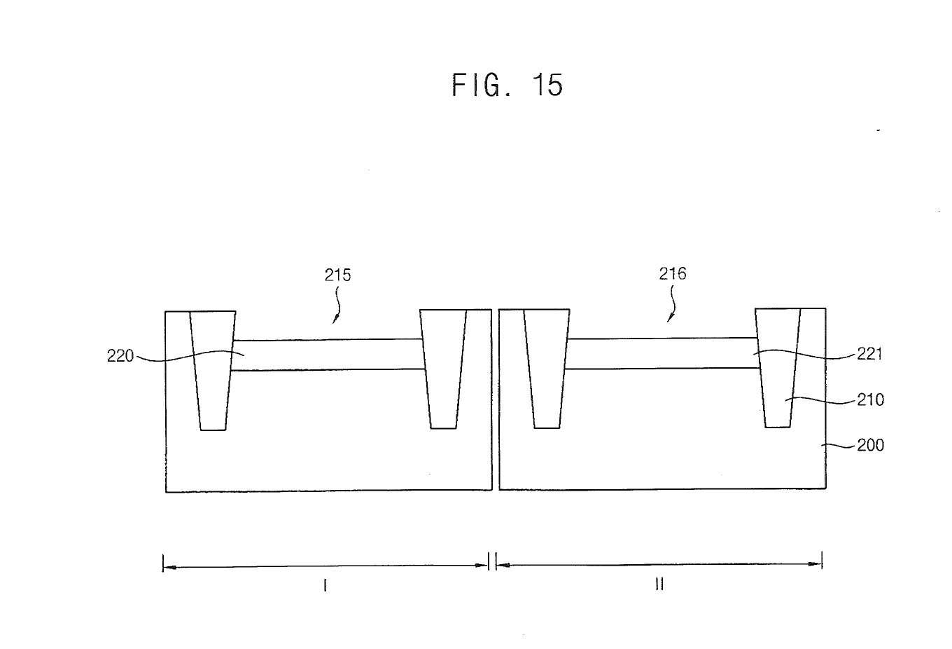

Referring to FIG. 15, upper portions of the first epitaxial layer 220 and the second epitaxial layer 221 may be removed by an etch back process or an etching process. In example embodiments, the upper portion of the first epitaxial layer 220 and the upper portion of the second epitaxial layer 221 may be removed simultaneously or separately. The first epitaxial layer 220 and the second epitaxial layer 221 may fill lower portions of the first recess 215 and the second recess 216, respectively.

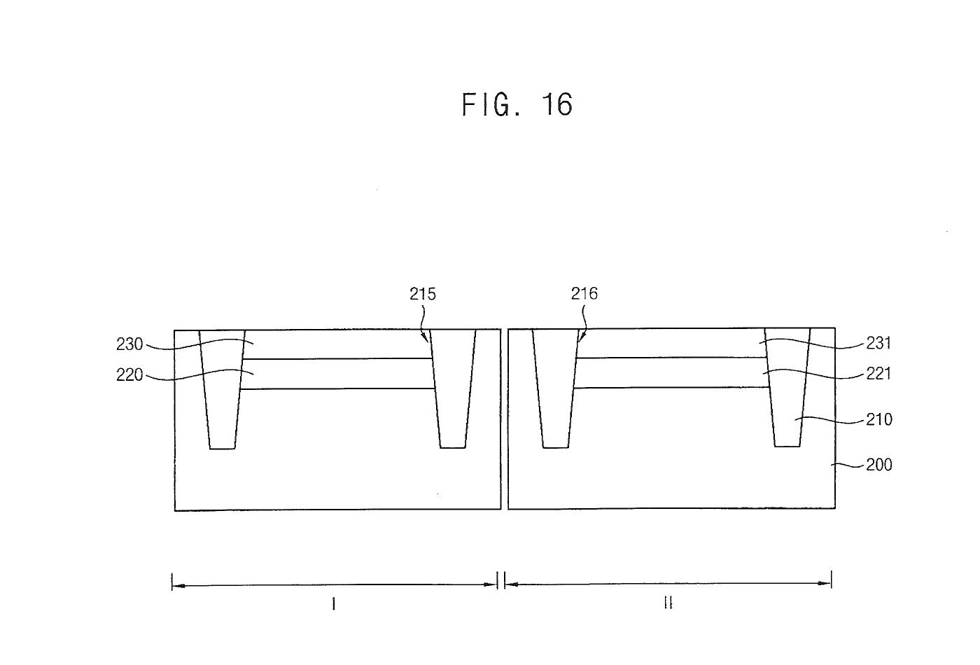

Referring to FIG. 16, a first channel layer 230 and a second channel layer 231 may be formed to fill upper portions of the first recess 215 and the second recess 216, respectively.

A preliminary channel layer may be formed on the substrate 200, the isolation layer pattern, the first epitaxial layer 220 and the second epitaxial layer 221 to fill the first recess 215 and the second recess 216, and the preliminary channel layer may be planarized until a top surface of the substrate 200 is exposed, thereby forming the first channel layer 230 and the second channel layer 231.

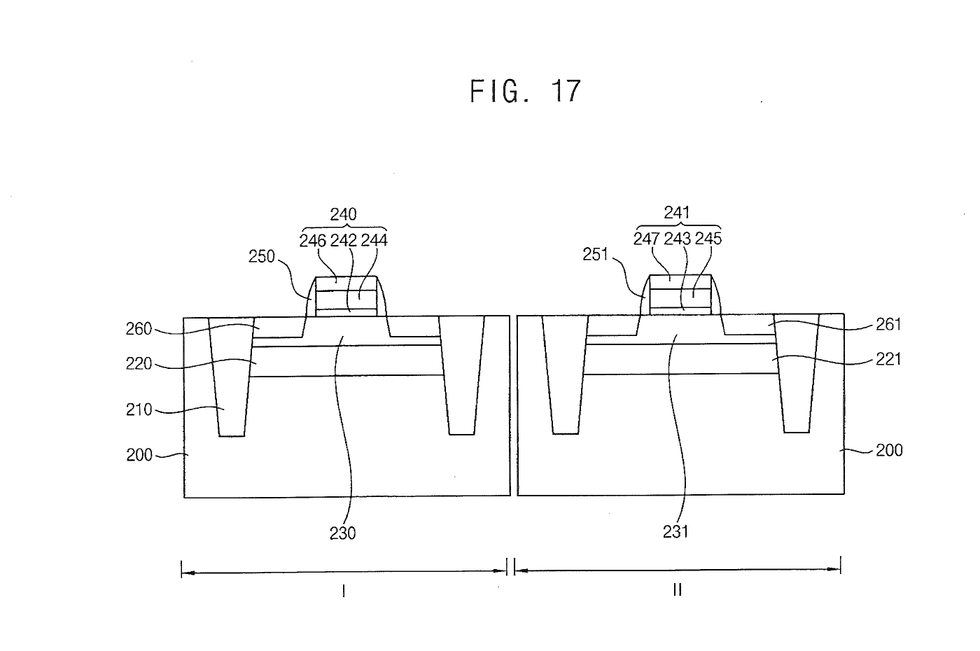

Referring to FIG. 17, a first gate structure 240 and a second gate structure 241 may be formed on the substrate 200 in the first region I and the second region II, a first spacer 240 and a second spacer 241 may be formed on sidewalls thereof, and then a first impurity region 260 and a second impurity region 261 may be formed at upper portions of the first channel layer 230 and the second channel layer 231.

The first and the second gate structures 240 and 241 may be formed by sequentially forming a gate insulation layer, a gate electrode layer and a gate mask layer, and by patterning the gate insulation layer, the gate electrode layer and the gate mask layer. Therefore, the first gate structure 240 may include a first gate insulation layer pattern 242, a first gate electrode 244 and a first gate mask 246 which may be sequentially stacked on the first channel layer 230, and the second gate structure 241 may include a second gate insulation layer pattern 243, a second gate electrode 245 and a second gate mask 247, which may be sequentially stacked on the second channel layer 231.

Then, a spacer layer may be formed on the substrate 200 and the isolation layer pattern 210 to cover the first and the second gate structures 240 and 241, and the spacer layer may be ansiotropically etched to form the first spacer 250 on a sidewall of the first gate structure 240 and the second spacer 251 on a sidewall of the second gate structure 241. For example, the first and the second spacers 250 and 251 may include silicon oxide, silicon nitride or silicon oxynitride.

After forming a third photoresist pattern covering the second region II of the substrate 200, an n-type impurity such as phosphorous (P) or arsenic (As) may be implanted into the upper portion of the first channel layer 230 using the third photoresist pattern and the first gate structure 240 as an ion implantation mask, thereby forming the first impurity region 260.

After forming a fourth photoresist pattern covering the first region I of the substrate 200, a p-type impurity may be implanted into the upper portion of the second channel layer 231 using the fourth photoresist pattern and the second gate structure 241 as an ion implantation mask, thereby forming the second impurity region 261.

Accordingly, the first channel layer 230, the first gate structure 240 and the first impurity region 260 may define the NMOS transistor, and the second channel layer 231, the second gate structure 241 and the second impurity region 261 may define the PMOS transistor.

According to example embodiments, the NMOS transistor may include the first epitaxial layer 220 including the silicon-germanium-tin (SiₓGe_{1-x-y}Sn_{y}) single crystal. The first epitaxial layer 220 may apply a tensile stress to the first channel layer 230, thereby improving electron mobility in the first channel layer 230. The PMOS transistor may include the second epitaxial layer 221 including the silicon-germanium single crystal. The second epitaxial layer 221 may apply a compression stress to the second channel layer 231, thereby improving hole mobility in the second channel layer 231.

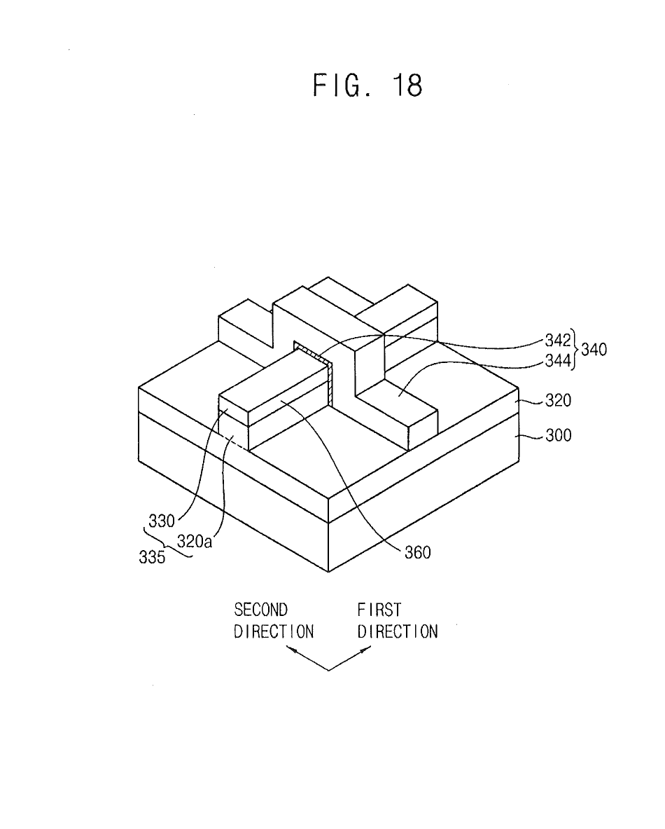

FIG. 18 is a perspective view illustrating a transistor in accordance with example embodiments.

Referring to FIG. 18, the transistor may include a first epitaxial layer 320, a first channel layer 330, a first gate structure 340 and the first impurity region 260.

The first epitaxial layer 320 may be disposed on a substrate 300. The first epitaxial layer 320 may include a first protrusion portion 320a, which may be projected in a direction substantially perpendicular to the top surface of the first epitaxial layer 320. The first protrusion portion 320a may extend in a first direction substantially parallel to the top surface of the first epitaxial layer 320.

The first epitaxial layer 320 and the first protrusion portion 320a may be integrally formed. In example embodiments, the first epitaxial layer 320 and the first protrusion portion 320a may include a material substantially the same as those of the first epitaxial layer 120 described with reference to FIG. 1. That is, the first epitaxial layer 320 may include a silicon-germanium-tin (SiₓGe_{1-x-y}Sn_{y}) single crystal having a lattice constant substantially larger than those of a germanium single crystal.

The first channel layer 330 may be disposed on the first protrusion portion 320a of the first epitaxial layer 320. The first channel layer 330 may directly contact the first protrusion portion 320a, and may extend in the first direction. Therefore, the first channel layer 330 and the first protrusion portion 320a may define an active pattern 335. In example embodiments, the first channel layer 330 may include a germanium single crystal. The first channel layer 330 may include the germanium single crystal having a lattice constant substantially smaller than that of the first protrusion portion 320a, so that the first protrusion portion 320a may apply a tensile stress to the first channel layer 330. Therefore, the first channel layer 330 may have improved electron mobility.

The first gate structure 340 may be disposed to cover the active pattern 335. The first gate structure 340 may have a predetermined width, and may extend in a second direction substantially perpendicular to the first direction. In example embodiments, the first gate structure 340 may include a first gate insulation layer pattern 342 and a first gate electrode 344.

The first gate insulation layer pattern 342 may be disposed on sidewalls of the first protrusion portion 320a and the first channel layer 330 and a top surface of the first channel layer 330. The first gate insulation layer pattern 342 may include a High-K dielectric material. The first gate electrode 346 may be disposed on the first gate insulation layer pattern 342 and the first epitaxial layer 320.

In other example embodiments, an additional epitaxial layer may be disposed between the substrate 300 and the first epitaxial layer 320 to relax a stress between the substrate 300 and the first epitaxial layer 320. Further, a barrier layer may be further disposed between the first protrusion portion 320a and the first channel layer 330 to reduce a leakage current. In another example embodiment, a capping layer may be disposed between the active pattern 335 and the gate insulation layer pattern 320 to improve an interface property.

The first impurity region 360 may be disposed at portions of the first channel layer which may be exposed by the first gate structure 340. In example embodiments, a plurality of first impurity regions 360 may be disposed to be spaced apart from each other, and each of the first impurity regions 360 may be used as a source region and a drain region.

According to example embodiments, the transistor having the projected active pattern 335 may include the first epitaxial layer 320 containing the silicon-germanium-tin (SiₓGe_{1-x-y}Sn_{y}) single crystal. Therefore, the transistor may have improved carrier mobility due to the tensile stress on the channel layer 330.

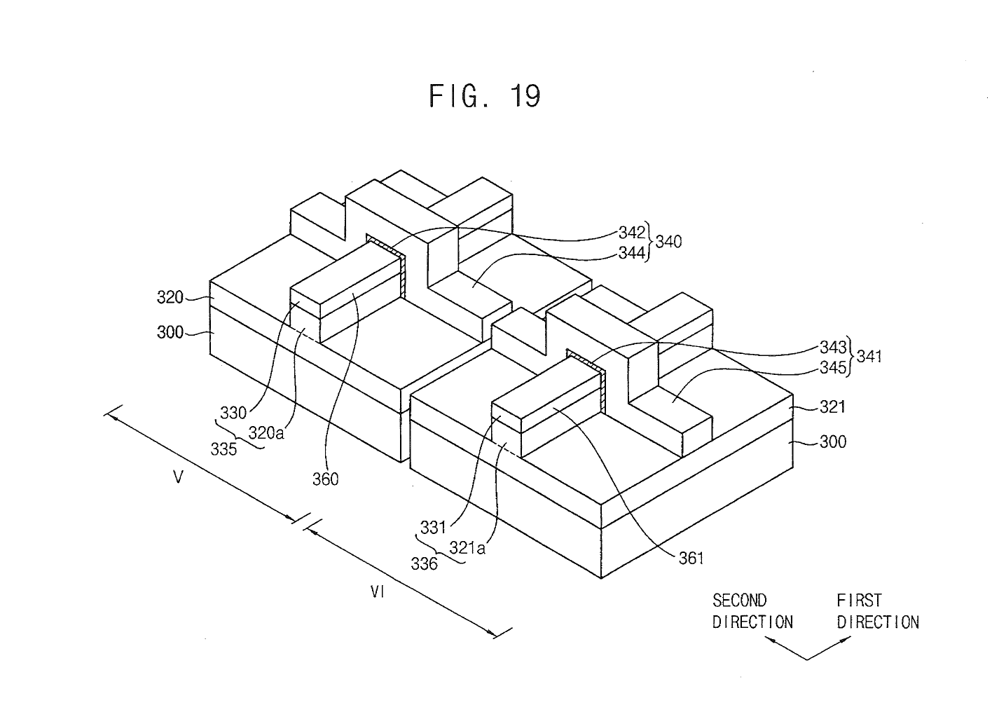

FIG. 19 is a perspective view illustrating a transistor in accordance with example embodiments.

Referring to FIG. 19, the transistor may include an NMOS transistor in a first region V on a substrate 300 and a PMOS transistor in a second region VI on the substrate 300.

The NMOS transistor may include a first epitaxial layer 320, a first channel layer 330, a first gate structure 340 and a first impurity region 360. The NMOS transistor may be substantially the same as or substantially similar to the transistor described with reference to FIG. 18, and, thus, repetitive explanations thereof may be omitted herein.

The PMOS transistor may include a second epitaxial layer 321, a second channel layer 331, a second gate structure 341 and a second impurity region 361. Further, the second epitaxial layer 321 may include a second protrusion portion 321a, and the second gate structure 341 may include a second gate insulation layer pattern 343 and a second gate electrode. The PMOS transistor may be substantially similar to the NMOS transistor except for the second epitaxial layer 321 and the second impurity region 361.

The second protrusion portion 321a of the second epitaxial layer 321 may directly contact the second channel layer 331. In example embodiments, the second epitaxial layer may include a silicon germanium single crystal, the silicon germanium single crystal may have a lattice constant and an energy bandgap substantially larger than those of a germanium single crystal. Therefore, the second epitaxial layer may apply a compression stress to the second channel layer 331, thereby improving hole mobility in the second channel layer 331,

On the other hand, the second impurity region 361 may include a p-type impurity such as boron (B), gallium (Ga), and the like,

According to example embodiments, the NMOS transistor may include the first epitaxial layer 320 including the silicon-germanium-tin (SiₓGe_{1-x-y}Sn_{y}) single crystal. The first epitaxial layer 320 may apply a tensile stress to the first channel layer 330, thereby improving electron mobility in the first channel layer 330. The PMOS transistor may include the second epitaxial layer 321 including the silicon-germanium single crystal. The second epitaxial layer 321 may apply a compression stress to the second channel layer 331, thereby improving hole mobility in the second channel layer 331.

FIG. 20 is a graph showing a lattice constant of silicon-germanium-tin (SiₓGe_{1-x-y}Sn_{y}) single crystal depending on the composition.

In the graph of FIG. 20, the x-axis represents silicon concentration of a silicon-germanium-tin (SiₓGe_{1-x-y}Sn_{y}) single crystal, and the y-axis represents tin concentration of the silicon-germanium-tin (SiₓGe_{1-x-y}Sn_{y}) single crystal. A line represents a composition of the silicon-germanium-tin (SiₓGe_{1-x-y}Sn_{y}) single crystal which has a lattice constant the same as that of a germanium single crystal.

The graph is divided into a plurality of composition regions depending on a lattice constant of the silicon-germanium-tin (SiₓGe_{1-x-y}Sn_{y}) single crystal. For example, “A1” represents a composition region in which a lattice constant of the silicon-germanium-tin (SiₓGe_{1-x-y}Sn_{y}) single crystal is about 0.016 A to about 0.018 A larger than that of the germanium single crystal. “A7” represents a composition region in which a lattice constant of the silicon-germanium-tin (SiₓGe_{1-x-y}Sn_{y}) single crystal is about 0.004 A to about 0.008 A smaller than that of the germanium single crystal.

FIG. 21 is a graph showing an energy bandgap of silicon-germanium-tin (SiₓGe_{1-x-y}Sn_{y}) single crystal depending on the composition.

In the graph of FIG. 21, the x-axis represents silicon concentration of a silicon-germanium-tin (SiₓGe_{1-x-y}Sn_{y}) single crystal, and the y-axis represents tin concentration of the silicon-germanium-tin (SiₓGe_{1-x-y}Sn_{y}) single crystal. A line IV-IV′ represents a composition of the silicon-germanium-tin (SiₓGe_{1-x-y}Sn_{y}) single crystal, which has an energy bandgap the same as that of a germanium single crystal.

The graph is divided into a plurality of composition regions depending on an energy bandgap of the silicon-germanium-tin (SiₓGe_{1-x-y}Sn_{y}) single crystal. For example, “B1” represents a composition region in which an energy bandgap of the silicon-germanium-tin (SiₓGe_{1-x-y}Sn_{y}) single crystal is about 0.96 eV to about 0.99 eV.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A transistor, comprising:
a first epitaxial layer disposed on a substrate, the first epitaxial layer including a silicon-germanium-tin (SiₓGe_{1-x-y}Sn_{y}) single crystal having a lattice constant greater than a lattice constant of a germanium (Ge) single crystal;
a channel layer disposed adjacent to the first epitaxial layer, the channel layer including the germanium (Ge) single crystal;
a gate structure disposed on the channel layer; and
an impurity region disposed at an upper portion of the channel layer adjacent to the gate structure.

2. The transistor of claim 1, wherein the silicon-germanium-tin single crystal has an energy bandgap greater than an energy bandgap of the germanium single crystal.

3. The transistor of claim 1, wherein the first epitaxial layer fills a lower portion of a recess on the substrate, and wherein the channel layer fills an upper portion of the recess on the substrate.

4. The transistor of claim 1, further comprising a barrier layer between the first epitaxial layer and the channel layer,
wherein the barrier layer includes a material having an energy bandgap greater than that of the germanium single crystal.

5. The transistor of claim 1, further comprising a second epitaxial layer disposed under the first epitaxial layer,
wherein the substrate includes a silicon (Si) single crystal, and wherein the second epitaxial layer includes a single crystal having a lattice constant less than a lattice constant of the silicon-germanium-tin single crystal and greater than a lattice constant of the silicon single crystal.

6. The transistor of claim 1, further comprising a capping layer between the channel layer and the gate structure,
wherein the capping layer includes silicon.

7. A transistor, comprising:
a epitaxial layer on a substrate, the epitaxial layer including a silicon-germanium-tin (SiₓGe_{1-x-y}Sn_{y}) single crystal having a lattice constant substantially greater than a lattice constant of a germanium (Ge) single crystal;
a protrusion portion projecting from an upper surface of the epitaxial layer, the protrusion portion extending in a first direction;
a channel layer extending in the first direction on the protrusion portion, the channel layer including the germanium (Ge) single crystal; and
a gate structure disposed on a sidewall of the protrusion portion, an upper surface of the channel layer and a sidewall of the channel layer, the gate structure extending in a second direction substantially perpendicular to the first direction.

8. A method of manufacturing a transistor, comprising:
partially removing an upper portion of a substrate to form a recess;
forming a first epitaxial layer to fill a lower portion of the recess, the first epitaxial layer including a silicon-germanium-tin (SiₓGe_{1-x-y}Sn_{y}) single crystal having a lattice constant greater than a lattice constant of a germanium (Ge) single crystal;
forming a channel layer to fill an upper portion of the recess, the channel layer including the germanium (Ge) single crystal;
forming a gate structure on the channel layer; and
implanting impurities at an upper portion of the channel layer adjacent to the gate structure.

9. The method of claim 8, wherein forming the first epitaxial layer includes performing a selective epitaxial growth process using a silicon source, a germanium source and a tin source.

10. The method of claim 8, wherein the silicon-germanium-tin single crystal has an energy bandgap greater than an energy bandgap of the germanium single crystal,

11. The method of claim 8, after forming the first epitaxial layer, further comprising performing a heat treatment process about the first epitaxial layer.

12. The method of claim 8, wherein forming the channel layer comprises:
performing a selective epitaxial growth process to form a preliminary channel layer filling the recess; and
planarizing the preliminary channel layer.

13. The method of claim 8, before forming the channel layer, further comprising forming a barrier layer by performing a selective epitaxial growth process on the first epitaxial layer,
wherein the barrier layer has an energy bandgap greater than an energy bandgap of the germanium single crystal.

14. The method of claim 8, after forming the channel layer, further comprising forming a capping layer including silicon on the channel layer.

15. The method of claim 8, before forming the first epitaxial layer, further comprising forming a second epitaxial layer filling a lower portion of the recess,
wherein the substrate includes a silicon single crystal, and wherein the second epitaxial layer includes a single crystal having a lattice constant less than a lattice constant of the silicon-germanium-tin single crystal and greater than a lattice constant of the silicon single crystal.

16. A transistor, comprising:
a first epitaxial layer disposed on a substrate, the first epitaxial layer including a silicon-germanium-tin (SiₓGe_{1-x-y}Sn_{y}) single crystal;
a channel layer disposed adjacent to the first epitaxial layer, the channel layer including a germanium (Ge) single crystal;
a gate structure disposed on the channel layer; and
an impurity region disposed at an upper portion of the channel layer adjacent to the gate structure;
wherein the silicon-germanium-tin single crystal has an energy bandgap greater than an energy bandgap of the germanium single crystal.

17. The transistor of claim 16, wherein the silicon-germanium-tin single crystal has a lattice constant greater than a lattice constant of the germanium single crystal.

18. The transistor of claim 16, wherein the germanium single crystal has a carrier mobility greater that of a silicon (Si) single crystal.

19. The transistor of claim 16, wherein the first epitaxial layer fills a lower portion of a recess on the substrate, and wherein the channel layer fills an upper portion of the recess on the substrate.

20. The transistor of claim 16, further comprising a barrier layer between the first epitaxial layer and the channel layer,
wherein the barrier layer includes a material having an energy bandgap greater than that of the germanium single crystal.
